(19) United States
(12) Patent Application Publication
(10) Pub. No.: US 2024/0169300 A1
(43) Pub. Date: May 23, 2024

(54) SYSTEMS AND METHODS FOR HYPOTHETICAL TESTING OF SUPPLY CHAIN OPTIMIZATION

(71) Applicant: Oii, Inc., Oakland, CA (US)

(72) Inventors: David Michael Evans, Welwyn Garden City (GB); Robert Derward Rogers, Oakland, CA (US); Vishnuvyas Sethumadhavan, Mountain View, CA (US)

(21) Appl. No.: 18/513,426

(22) Filed: Nov. 17, 2023

Related U.S. Application Data
(60) Provisional application No. 63/384,596, filed on Nov. 21, 2022.

(51) Int. Cl. G06Q 10/067; G06F 30/27; G06Q 10/04; G06Q 10/08

(52) U.S. Cl. CPC G06Q 10/067; G06F 30/27; G06Q 10/04; G06Q 10/08

(57) ABSTRACT

The present invention relates to systems and methods for hypothetical testing of a supply chain optimization. The computerized method for hypothetical optimization of a supply chain receives a hypothetical optimization query, generates variable definitions responsive to the query, generates scope definitions responsive to the query, generates presentation definitions and generates an optimization parameter set using the variable definitions and the scope definitions. The parameter set is used to optimize a hypothetical supply chain via an artificial intelligence (AI) modeling platform. One or more recommendations are generated based upon the optimized hypothetical supply chain.

### CROSS REFERENCE TO RELATED APPLICATIONS

This application claims the benefit and priority of U.S. Provisional Application No. 63/384,596, filed on Nov. 21, 2022 (Attorney Docket OIIP-2203-P), entitled “SYSTEMS AND METHODS FOR HYPOTHETICAL TESTING OF SUPPLY CHAIN OPTIMIZATION”, the contents of which is incorporated herein in its entirety by this reference.

### BACKGROUND

The present invention relates to systems and methods for hypothetical testing of supply chain optimizations.

Configuring a supply chain planning system correctly is a complex task and one that most planning systems do not address. Identifying and configuring the optimal supply chain requires multivariate mathematical modeling and a near infinity of potential settings, despite this supply chains typically are configured manually. Supply chain planning systems rely on Planners to set the right parameters even though failure to find the optimal parameters results in ineffective plans that will propagate across the network, regardless of the effectiveness of the software.

It is a significant problem to rely upon a planner for supply chain management because finding the right configuration—even in relatively simple supply chains—is extremely difficult to achieve. There are simply too many variables to consider and multitude of potential service versus cost outcomes. In addition, real-world supply chains are often global, making the task exponentially more complicated. Even for experienced planners this is an insurmountable challenge.

As a result, many supply chains are set up and planned in a significantly suboptimal way, resulting in a combination of issues such as Service Failures and Missed Sales, Overstocks on some items and under-stock on others, Factory Inefficiencies, Reactive rather than Strategic Plans, and High Costs of Waste (for example when products expire while in inventory).

Identifying an optimal set up requires detailed evaluation of the cost versus service implications of the millions of potential configuration options across the end-to-end supply chain network encompassing dimensions such as Supply Chain Variability, Network Design, Product segmentation, Inventory Strategy, Factory sequence and rhythm.

Artificial Intelligence and machine learning techniques (AI/ML) are a new generation of algorithms that demonstrate self-learning and the capability to make decisions. Its power is its ability to process multiple data inputs simultaneously and to use this information to compare outcomes, make informed choices and to self-correct so that those choices improve over time.

In addition to determining a local optimization of a supply chain, different planners, industries and companies may have varying concerns and priorities. It is helpful to be able to model out “what-if” scenarios to address these concerns.

It is therefore apparent that there is an urgent need to perform sophisticated AI driven supply chain optimizations responsive to hypothetical scenarios. Such systems and methods allow planners to alter supply chain priorities, and model out concerns that may impact future supply chain situations.

### SUMMARY

To achieve the foregoing and in accordance with the present invention, systems and methods for hypothetical testing of a supply chain optimization is provided. Such systems and methods allow planners to model scenarios where different priorities to the supply chain are made, and responsive to changing conditions to allow for a more robust and forward-looking supply chain management.

In some embodiments, the computerized method for hypothetical optimization of a supply chain receives a hypothetical optimization query, generates variable definitions responsive to the query, generates scope definitions responsive to the query, generates presentation definitions and generates an optimization parameter set using the variable definitions and the scope definitions. The parameter set is used to optimize a hypothetical supply chain via an artificial intelligence (AI) modeling platform. One or more recommendations are generated based upon the optimized hypothetical supply chain.

In some embodiments, the variable definitions include at least one of demand variables, service level target (SLT) variables, source variables, cost weight variables, cost variables, mode and vendor variables, and complex scenario variables. The SLT variables are computed using an M^{N} matrix, which may be a 3^{N} matrix.

In some embodiments, the parameter set is defined as:

P=SLTₘᵢₙ≥ΣwᵢCᵢ

Where P is the set of parameters for a given product, SLTₘᵢₙ is the minimum service level target for the given product, and Cᵢ is the series of costs for the supply chain and wᵢ are the weights associated with each cost. The weighted cost vector is defined as:

wᵢCᵢ=[w_{d}C_{d},w_{ch}C_{ch},wₛₕCₛₕ,w_{w}C_{w},w_{ci}C_{ci},w_{f}C_{f},wₛₒCₛₒ,w_{cbn}C_{cbn}]

Where C_{d} is the cost of discards, C_{ch} is the cost of changeovers, Cₛₕ is the cost of shipping, C_{w} is the cost of warehousing, C_{ci} is the cost of inventory, C_{f} is the cost of freshness, Cₛₒ is the cost of stockouts and C_{cbn} is the cost of cardon emissions. In a default optimization, each of the weights are set to one.

The scope definitions include at least one of a specific item, a specific product family, a specific product area, a region, a market, a network group, a trade route and a portfolio. The presentation definitions include at least one of plotting cost as a function of a query variable, plotting service level as a function of the query variable, recommendation of a best value subject to the query variable, comparison of the optimized hypothetical supply chain versus a current supply chain, and precomputed alerts.

Note that the various features of the present invention described above may be practiced alone or in combination. These and other features of the present invention will be described in more detail below in the detailed description of the invention and in conjunction with the following figures.

### BRIEF DESCRIPTION OF THE DRAWINGS

In order that the present invention may be more clearly ascertained, some embodiments will now be described, by way of example, with reference to the accompanying drawings, in which:

FIG. 1 is a block diagram illustrating an Orchestrated Intelligent Supply Chain Ecosystem, in accordance with one embodiment of the present invention;

FIG. 2 is a block diagram illustrating one embodiment of an Optimizer for the Ecosystem of FIG. 1;

FIG. 3 is a block diagram illustrating an example of the hypothetical scenario module, in accordance with some embodiments;

FIG. 4 is a block diagram illustrating an example of the optimization module, in accordance with some embodiments;

FIG. 5 is a block diagram illustrating an example of the performance prediction module, in accordance with some embodiments;

FIG. 6 is a block diagram illustrating an example of the optimized parameters and sensitivities computation module, in accordance with some embodiments;

FIG. 7 is a flow diagrams illustrating an example process of modeling a hypothetical scenario for a supply chain optimization;

FIG. 8 is a flow diagrams illustrating an example sub-process of parameter set generation;

FIG. 9 is a flow diagrams illustrating an example sub-process of variable definition;

FIG. 10 is a flow diagrams illustrating an example sub-process of a complex scenario workflow;

FIG. 11 is an illustration of an example 3^{N} service level matrix; and

FIGS. 12A and 12B illustrate an exemplary computer system for implementing the Optimizer of FIG. 2.

### DETAILED DESCRIPTION

The present invention will now be described in detail with reference to several embodiments thereof as illustrated in the accompanying drawings. In the following description, numerous specific details are set forth in order to provide a thorough understanding of embodiments of the present invention. It will be apparent, however, to one skilled in the art, that embodiments may be practiced without some or all of these specific details. In other instances, well known process steps and/or structures have not been described in detail in order to not unnecessarily obscure the present invention. The features and advantages of embodiments may be better understood with reference to the drawings and discussions that follow.

Aspects, features and advantages of exemplary embodiments of the present invention will become better understood with regard to the following description in connection with the accompanying drawing(s). It should be apparent to those skilled in the art that the described embodiments of the present invention provided herein are illustrative only and not limiting, having been presented by way of example only. All features disclosed in this description may be replaced by alternative features serving the same or similar purpose, unless expressly stated otherwise. Therefore, numerous other embodiments of the modifications thereof are contemplated as falling within the scope of the present invention as defined herein and equivalents thereto. Hence, use of absolute and/or sequential terms, such as, for example, “always,” “will,” “will not,” “shall,” “shall not,” “must,” “must not,” “first,” “initially,” “next,” “subsequently,” “before,” “after,” “lastly,” and “finally,” are not meant to limit the scope of the present invention as the embodiments disclosed herein are merely exemplary.

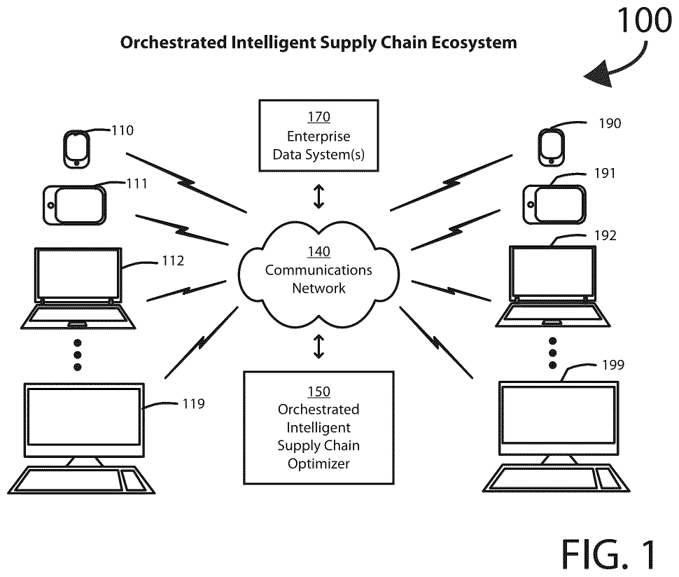

The present invention relates to systems and methods for running hypothetical scenarios in an intelligent optimized supply chain. To facilitate discussion, FIG. 1 is a block diagram of an Orchestrated Intelligent Supply Chain Ecosystem 100 illustrating an Orchestrated Intelligent Supply Chain Optimizer 150 coupled to Enterprise Data System(s) 170 and stakeholders' communication devices 110 to 119 and 190 to 199 via a communication network 140 such as the Internet, wide area network, cellular network, corporate network, or some combination thereof. Depending on the implementation, exemplary stakeholders can include one or more groups of managers (including, but not limited to, operations managers, supply chain managers, IT managers), planners, data scientists, data miners, data engineers, data providers, manufacturers, distributors, and retailers.

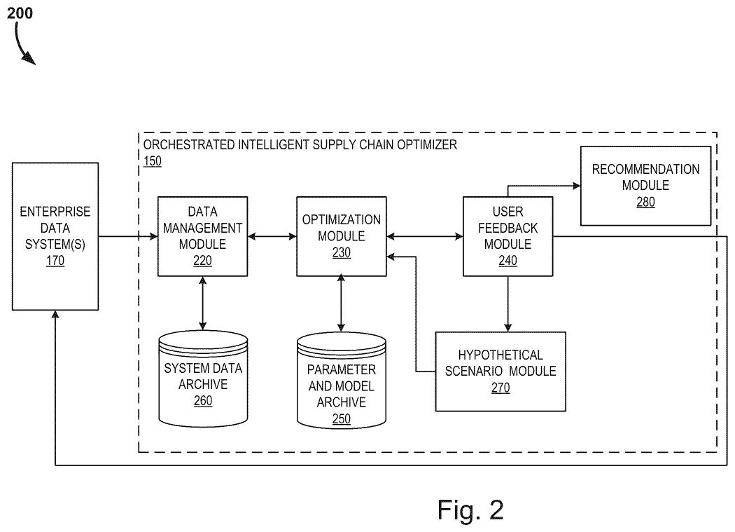

The core of the supply chain optimizer 150 is presented in greater detail in reference to FIG. 2. The enterprise data systems 170 from various third-party entities who are seeking supply chain optimization (commonly referred to as “clients” or “customers”) provides information regarding the client's existing supply chain to the optimizer 150. This data is initially provided to the data management module 220 for ingestion. The data provided from the enterprise data system(s) 170 is in an unusable form for the downstream optimization module 230. Generally, each client has different outputs of their supply chain data based upon the backend system (or systems) they employ, and due to personalization and customizations to the data format and content. This creates a significant hurdle for the supply chain optimizer 150 ultimate usage of the client's data. The data management module 220 solves these issues through complicated AI-driven data ingestion techniques. The Data Management Module 220 configures connections to data from customer enterprise data systems (EDS) and receives these data in both asynchronous processes (batch data import) and synchronous processes (ongoing/live data feeds). These data are then combined with any system data previously stored in System Data Archive 260 to create a representation of the supply chain network. This data is of four distinct types (examples are not exhaustive): Item Master Data (fixed data related to the item): code, description, price, UOM etc.; Item Parameter Data which determines how the network is currently planned. Examples are Current Safety Stock Levels, Delivery Frequency, Order Multiples; Supply Chain Variability data—Examples are product-level monthly demand history, delivery performance history or characteristics; Strategic Objective Parameters/Constraints such as Service Targets, Site sensitivity to complexity, cost of holding stock, Transport Costs etc.

After the data has been ingested by the data management module 220, copies of relevant formatted data are stored in the system data archive 260. The system data archive includes a myriad of necessary data, including historical demand data, historical forecast data, historical inventory levels at different locations (nodes) in the supply chain for different products, supply chain site information, supply chain product information, information on linkages between sites including transport times, transport time variability, transport methods and costs, supply chain configuration parameters (e.g. replenishment strategies and the parameters for each strategy at each location for each product), product cost of goods sold (“COGS”), product retail or list price at each location, factory changeover costs, carbon emission by different components of the supply chain, service level targets, market segmentation for products, among many others.

The optimization module 230 performs the heavy lifting of the optimization process. It consumes the cleansed, formatted and aggregated data from the data management module 220 and performs the optimization of the supply chain, leveraging AI/ML models, subject to specific constraints. These constraints, models, and other parameters are stored in a parameter and model archive 250. As the models are developed, implemented, and feedback is received—the models may be trained on said feedback. The updated models are then stored, typically in a versioned manner, back in the parameter and model archive 250 for subsequent usage.

Output of the optimization module 230 is generally fed to the user feedback module 240 for presentation of the results, and importantly, pushing the recommendations to the enterprise data system 170 of relevance for implementation of the recommendations through a recommendation module 280. The recommendation module 280 may filter results of various hypothetical scenarios that have been optimized for (discussed in significant detail below) and identify scenarios that have statistically significant impact upon service levels, costs, or risks (e.g., freshness of product, reduced stockout risk, etc.). For the purposes of this disclosure, ‘statistically significant’ may refer to a change in the values above 10%, or above 0.2 standard deviations. In contrast, ‘roughly statistically significant’ may be above 5% and 0.1 standard deviations.

This results in a feedback loop, where the resulting impacts of the adopted recommendations are fed back into the system, and the models may be refined based upon the actual impacts measured (vs the modeled/expected impacts). With improved models, and changes in conditions, the process repeats with optimization and output.

In addition to pushing the recommendations to the client, the user feedback model 240 is able to provide analysis of the actual impacts of the supply chain (e.g., cost, service levels, inventory levels per node, changeover events, etc.) versus what is expected based upon the optimized parameters. This enables the client to visualize and react to the optimized conditions, and in some embodiments, engage in modulating possible parameters in order to analyze the possible impacts.

Input from a user via the feedback module 240 may be fed into a hypothetical scenario module 270 which consumes the query by the user for a “what-if” scenario and converts the query into a set of optimization parameters. These parameters are fed into the optimization module 230 for processing to generate outputs regarding the ‘best’ supply chain configurations for the given hypothetical scenario. These outputs are again fed to the user feedback module for presentation to the user, and generation of possible recommendations by the recommendation module 280.

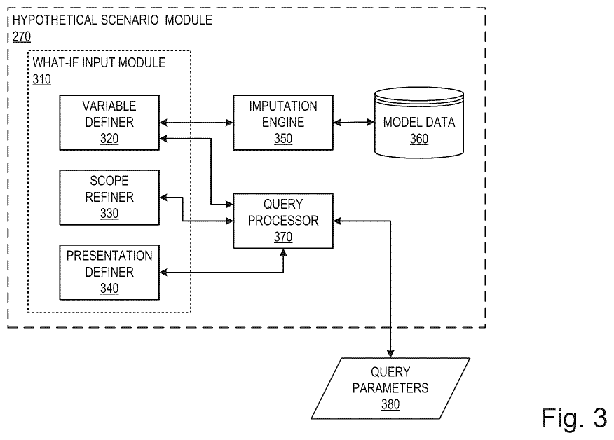

FIG. 3 provides a more detailed illustration of the hypothetical scenario module 270. Initially a query is received from the feedback module 240. This query may be an alteration of specific optimization inputs or may include a natural language query. For example, a user could select to increase the weight of a carbon cost by 3 times (alteration of the specific optimization input), or could ask the system “what if we increased the cost of carbon emissions by 300 percent?” (a natural language query). Although not illustrated, the what-if input module 310 may include a natural language (NL) processing unit that consumes such NL queries and converts them into specific optimization objectives. Many NL processing techniques are known in the art, and as such, for the sake of brevity, such systems will not be discussed in great detail herein. Suffice it to say, the query may be tokenized, specific named entities that correspond to optimization inputs are identified, and the change indicated by the surrounding language are applied to the optimization input for the what-if scenario.

The query then undergoes three stages of analysis to generate an optimization parameter set. These include defining the variables of the optimization in the variable definer 320, refining the scope of the optimization at the scope refiner 330, and while not directly related to the optimization itself, the presentation definer 340 may take input from the user to provide the display of the resulting optimization. In alternate embodiments, the presentation definer 340 may take the results of the what-if optimization and determine which presentations are best suited for the results.

The variable definer 320 generally can alter different optimization input variables without additional data; however, in some more complex hypotheticals, unknown values are required for the generation of the optimization parameter set. For these situations, imputation engine 350 may leverage existing model data 360 to impute missing data. Confidence in the imputation may also be calculated by the imputation engine 350, which is used in downstream analysis as to the veracity of the hypothetical results. After any imputation step, a human may be requested to review imputation results to confirm or reject the imputation results. In some embodiments the imputation may generate three (or some other manageable number) of desired scenarios/recommendations. The user may then select from the recommendations the ‘best’ solution given their specific query. This feedback may be utilized in turn to train the machine learning algorithms.

The output of the variable definer 320 and the scope refiner 330 is compiled by the query processor 370 to generate a set of query parameters 380. These query parameters 380 are a set of optimization parameters and constraints that are consumed by the optimization engine for the processing of the hypothetical scenario.

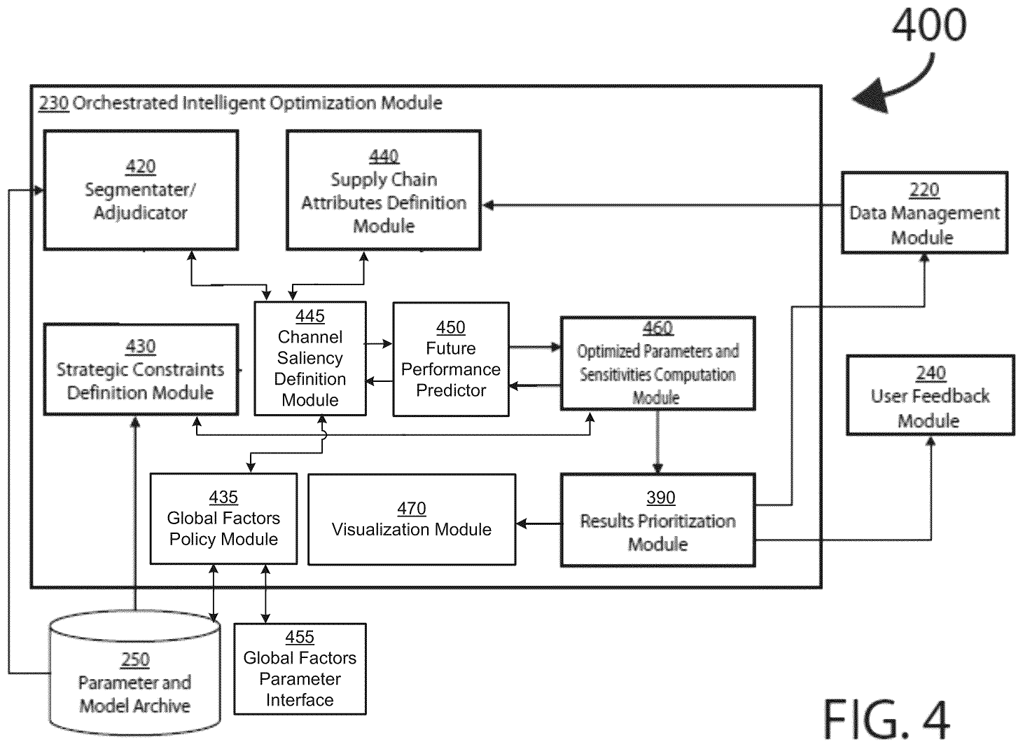

Turning to FIG. 4, a more detailed illustration of the optimization module 230 is provided. In a Global Factors Parameter Interface 455, external inputs to Global Factors are retrieved and made available to the Orchestrated Intelligent Supply Chain Ecosystem 100. These external inputs can include, but are not limited to, the types of carbon tax, carbon exchange trading systems and voluntary carbon offset programs that the customer is enrolled in along with parameters that determine their impacts on the customer. One important example of such parameters is cost data for carbon offsets retrieved from live systems (which may include online marketplaces, transaction exchanges, live bidding markets, or external price lists and interfaces) which can be used to compute accurate cost impacts of choices of supply chain configuration, and in some cases even execute transactions to lock in these sources at the time they are needed to offset supply chain activity.

Sensitivity results from Optimized Parameters and Sensitivities Computation Module 460 which identify sensitivity of optimization results to variability in system attributes (for example, increased probability of stockout as a result of decreased delivery performance in a specific part of the network) are presented to users of the Data Management Module 220 to inform Data Management activities. In the example given above (stockout as a function of delivery performance) this capability would identify the need to measure delivery performance more accurately, improve delivery performance in a specific part of the network, or both.

When the permissions of the logged-in users do not allow access to view or change some data in the Orchestrated Intelligent Supply Chain Ecosystem 100 appropriate selection and filtering of data may be performed in this module.

In some embodiments, the Data Management Module 220 tracks ongoing differences between the parameters that were recommended by the OI system at the time of the last parameter export and the parameters deployed in the system of record (imported through customer database). This process of creating a baseline at each export, updating supply chain characteristics such as total cost, total inventory, end-to-end supply chain throughput and lead time variability (all of which may be broken down in a number of ways including by network, subnetwork, node, region, leafSKU, productSKU, product family, among many others) and updating recommended parameters upon data export represents critical functionality for supply chain managers and organizational leaders. In some embodiments these data are represented in tabular and graphical forms in the OI user interface.

In some embodiments, the Data Management Module 220 receives availability data for supply chain resources that may include supplies, materials and other items used in the manufacturing, packaging and shipping of goods. These data may include time series of expected delivery dates and amounts of such resources or may indicate maximum average amounts of material available during different time periods. A key impact of such data is to constrain activities in the supply chain that consume these resources. For example, if the packaging of a product requires a certain size box and only 10,000 boxes are available within a certain time period, then no more than 10,000 of the product can be packages using these boxes during that period. (any input to the system at any level in the supply chain)

In Optimization Module 230, the primary optimization and analysis functions of the Orchestrated Intelligent Supply Chain Optimizer 150 are executed. This module receives data from the Data Management Module 220 and from 250 Parameter and Model Archive. It also interacts with the user to input/update strategic objective parameters and constraints that are used to inform the tradeoffs and cost function used in the optimization process.

While Item Master, Item Parameter and Variability data is set and unchanging based on imports (using the most up to date information in 220) Strategic Objective Parameters/Constraints are defined by the user as a driver of the way the optimization process works influencing sensitivity of the model to particular goals and constraints and enabling a level of interactive-ness in the modelling process.

Several analytical processes are performed in Optimization Module 230, including segmentation of products based on most recent available data and adjudication of updated segmentation with previous segmentation results, determination of current supply chain network (which in some embodiments includes use of machine learning and AI models to recommend improvements upon an existing network and facilitate implementation of these improvements, a.k.a. AI-augmented network design optimization), prediction of future performance of the supply chain network for different supply chain parameter settings based on a variety of supply chain network configuration assumptions, analysis of optimal supply chain parameter settings given both strategic objectives (e.g. desired Service Levels (SL) for individual products or groups of products) and system-level constraints (e.g. upper limits of the number of orders a supply site can service per time period), and optimization of the presentation of results to planners and other users (in some embodiments, machine learning and/or AI models are used to recommend contents and display parameters of supply chain optimization results).

Optimization Module 230 records results of the various computations (AI-augmented network design optimization) along with user parameter selections and other computational results (e.g., cost and performance implications of choosing non-optimal parameters) in 250 Parameter and Model Archive.

Optimization Module 230 presents the optimized results to users in the User Feedback Module 240 where users (e.g., planners) interact with these results, and the results of such interactions are then transmitted back to the Optimization Module 230 as part of the Machine Learning process driving further optimization of the ML and AI models used by the module. The data is archived so that past decisions can be restored.

User Feedback Module 240 receives results from the Optimization Module 230 that have been conditioned for optimal usefulness and impact. The user may interact with these results in a number of ways, including but not limited to accepting the recommended parameters, modifying the recommended parameters, rejecting the recommended parameters, commenting on results, initiating requests and actions based on the results (for example, a request to modify a network or system constraint, or change a Service Level value for one or more products or segments) and submitting and/or exporting results to the planning system for implementation. Feedback, responses, comments, requests and other input from users are sent back to the Optimization Module 230 for further processing. In some embodiments, feedback, responses, requests and other input from users are sent to other customer systems outside the Orchestrated Intelligent Supply Chain Optimizer 150 as well.

The Parameter and Model Archive 250 acts as a system for storage and retrieval of information relating to the optimization and feedback process, including but not limited to: information relating to past and current model parameters, model designs, user inputs, system settings, supply chain network optimizations, recommendations and changes, intermediate computational results, computed implications of user decisions and inputs, and in some embodiments external inputs to the network design process generated by machine learning and AI systems operating on data external to the system (e.g. financial projections, news articles about markets, companies and products, social media, etc.). This archive acts as a system of record for which parameters values were recommended by the Orchestrated Intelligent Supply Chain Optimizer 150 and which values were actually put into operation by planners. As such it enables the Orchestrated Intelligent Supply Chain Optimizer 150 to both model the optimal supply chain configuration but to also monitor compliance with the recommendations to flag where failure to comply resulted in costs/issues. It also enables utilization of past results versus actuals as a means to facilitate the self-learning aspect of the ML model such that future configurations improve as the model gains more insight on what decisions drive the best outcomes.

FIG. 4 further illustrates the functionality of Orchestrated Intelligent Optimization Module 230 in greater detail. The primary function of the Segmenter/Adjudicator 420 is to apply grouping logic to products in order to facilitate the supply chain optimization process. In some embodiments, this may be an auto-segmenter that allows the data to automatically identify and suggest a segmentation scheme for the products in the supply chain. There can be multiple simultaneous segmentations or groupings in use at any time, which may have a variety of purposes. For example, products might be organized into classes based on two parameters: their financial value to the organization (e.g., annual revenue) and the variability of demand for the product (e.g. coefficient of variance or CoV). Products in different classes may be managed under different strategies, each of which implies different choices for supply chain parameters and stock ordering methodology (e.g., make-to-stock or make-to-order). These choices then directly influence the prediction and optimization strategies employed in Orchestrated Intelligent Supply Chain Optimizer 150. Another example of segmentation that could impact optimization results is a product type, for example drugs for oncology, HIV and hepatitis might be grouped together into three classes according to their intended uses. In some embodiments, such groupings might directly determine minimum Service Level values for products in each group. Because multiple segmentation or grouping mappings may be used simultaneously, there is also envisioned additional algorithmic structure that can harmonize among different groupings to ensure that ultimately product segmentation or grouping assignments are unique, thus ensuring that parameter assignments are also unique.

In some embodiments, the Segmenter/Adjudicator 420 module might assign groupings following a variety of methodologies. For example, in some embodiments, segmentation may be determined by the customer and passed directly to the system as a product-level attribute or as a mapping or other algorithmic formulation. In other embodiments, segmentation might be computed from data available to the system (product attributes from Data Management Module 220, for example, or information inferred from structured and unstructured sources outside of the customer system, such as text from web sites, healthcare documents, competitive or market analysis reports, or social media). In some embodiments, machine learning and AI may be used to directly construct useful segmentation strategies (for example using clustering algorithms or dimensionality reduction algorithms such as Latent Dirichlet Allocation).

The segmentation activities performed in Segmenter/Adjudicator 420 may be performed periodically (timing could be ad hoc or on a specific cadence, and timing could depend on the specific segmentation algorithm being applied) to ensure that segmentation or grouping of each product is still appropriate to the current conditions. For example, if segmentation depends upon product CoV and the measured product CoV has changed for any reason over time, then it is important for the system to detect this situation and alert the customer.

This is where the Adjudication function of Segmenter/Adjudicator 420 is performed. At any time, an appropriately permissioned user of the system might override the recommended segmentation or grouping of a specific product and set parameters manually. Additionally, when the assigned segmentation or grouping of a product changes over time, such a user may choose to accept or override the newly computed grouping. Adjudication allows users to visualize segmentation or grouping assignments and to assign new values as underlying data or corporate strategies evolve.

An important role of the Channel Saliency Definition Module is to assign relative importance, priority or weighting values (“Channel Saliency Values”) to specific products for specific channels (a channel may be an end customer, consumer or category or grouping of customers or consumers). Channel Saliency Values are used in the optimization process (Orchestrated Intelligent Optimization Module 230) to allocate inventory or product supply to channels in an automated, intelligent manner when product supplies are constrained, as when there is a limitation on availability of one or more supply chain resources. An important example is the allocation of vaccines when the number of individuals in a region exceeds the number of vaccine doses that are available to serve that region. In this case, public health policies such as prioritizing vaccines for older individuals, or for those with specific comorbidities or vulnerabilities, are cast in terms of Channel Saliency Values (patients with age over 80 would have higher values than younger patients, for example) and the optimization is carried out to ensure that the most optimal method of achieving the public health policy objectives for the vaccine program would be carried out.

The Strategic Parameters and Constraints Definition Module 430 module allows the user to identify constraints on allowed supply chain configurations to ensure compliance with both physical limitations of systems and corporate governance and strategy. For example, without constraints, the Optimized Parameters and Sensitivities Computation Module 460 module might find optimal supply chain parameters settings for products individually, without any regard for the system-wide implications of such settings. As a specific example of this, individual product-level optimization may imply a very large number of frequent reorders of a group of products that are being manufactured by a specific supply site. It may not be physically possible or financially feasible for this supply site to service such a large number of reorder requests (which generally imply reconfiguring the actual manufacturing systems among many other effects), so a constraint limiting the total number of orders to a supply site would need to be included in the computations carried out by the Optimized Parameters and Sensitivities Computation Module 460. Other examples are high transportation costs on particular Supply Customer routings, Pallet spacing in a warehouse and the impact of bulky items on such a modelling outcome.

Other strategic constraints might express business imperatives, such as reducing overall inventory in parts of the supply chain or ensuring that the risk of a stockout of a critical product or group of products be below a specific level.

In many cases, supply constraints can impact many different supply chains simultaneously, creating a need to define global strategic parameters that govern the optimization of multiple products simultaneously in Strategic Parameters and Constraints Definition Module 430. These global strategic parameters are used to regulate the application of Channel Saliency values to define the optimal allocation of products across different coupled markets and supply chains.

The Global Factors Policy Module 435 allows the user to configure the inputs, computations, and outputs required to satisfy the user's Global Factors Policy. Global Factors refer to all impacts of the supply chain that are not directly part of traditional supply chain costing and logistics activities. Global Factors can have both internal (internal to customer) and external impacts. An example of a Global Factor is environmental impact of the operations defined within the supply chain, and a specific example of an environmental impact could be carbon emissions footprint. For the example of a carbon emissions footprint, different supply chain configurations and choices can have environmental and cost implications. Specifically, the Orchestrated Intelligent Supply Chain Ecosystem 100 can compute the explicit costs of land and air transportation, the implied costs of these choices induced by differences in delivery time, inventory holding requirements and delivery time variability and also the different carbon emissions costs induced by these choices. Carrying the example further, depending upon whether the customer is subject to carbon taxes, requirements for carbon offsets or even voluntary carbon offsets, the costs of these factors can be included in the computation of costs implied by each supply chain configuration decision.

The Global Factors Policy Module 435 considers at least three areas of factor for the inclusion of Global Factors in supply chain optimization: Explicit sources of Global Factors costs, the ultimate disposition and publication of Global Factors results and the strategic objectives and preferences of the customer in the computation of Global Factors. The first of these, explicit sources of Global Factors costs, includes information on what kinds of Global Factors costs the organization is subject to (for example, carbon taxes, environmental offsets and/or credits, compliance offsets, voluntary offsets, etc.) and what the specific costs for these factors are. These inputs are imported by Global Factors Parameter Interface 255, including in some cases real time information pertaining to live market costs of carbon offsets or other commodities. The ultimate disposition and publication of Global factors pertains to internal and external reporting and display of Global Factors results. Outputs in this category include, but are not limited to, internal dashboards and reports of costs, tradeoffs and impacts of supply chain optimization activities, external reporting for regulatory compliance or for public communication and interaction with live interfaces, including transactional markets for environmental offsets (where bids might be published for the required offset commodities and actual purchase and sale transactions of these commodities might be carried out). Strategic objectives and preferences for the organization pertaining to Global Factors could include many factors that impact how the costs are computed and how tradeoffs are valued, such as which types and sources of offset commodities might be acceptable or preferred for purchase, how much “effective cost” for Global Factors should be taken into account (for example is an offset cost of $1000 equivalent to a “hard cost” of $1000 to transport materials from one location to another), and what publication, reporting, dashboard and tracking activities should take place within the organization. Taken together, these three categories of input parameters determine the cost and tradeoff structure that drives optimizations of a supply chain in a way that includes Global Factors.

The Supply Chain Attributes Definition Module 440 objective is to characterize the physical and performance characteristics of the relevant parts of a supply chain quantitatively. The definition of “relevant parts” of a supply chain in this context is any physical or logical aspect of a supply chain that materially influences the selection or computation of optimal supply chain operating parameters. For example, while a customer's supply chain globally may include supply chain networks in North America and Europe, it may be the case that these supply chains are entirely decoupled and do not influence each other's behavior. In this case then, the “relevant parts” of the supply chain in the optimization of product delivery to Spain would include the European supply chain but not the North American supply chain. This is not to imply that relevancy is only determined by geographical factors. As another example, it may be that the performance of a leaf node of a supply chain can be completely characterized by the delivery performance of a single node upstream along with total transportation costs to the leaf node and manufacturing costs for the product. In this case, it may be quantitatively acceptable to ignore supply chain network nodes between the manufacturer and the first node upstream from the leaf node, effectively rendering those intermediate nodes as not “relevant parts” of the network for the purpose of optimizing the leaf node operating parameters. This is an important point, because it is a unique characteristic of the present invention that complete knowledge of all supply chain attributes in a customer's entire supply chain is not required to arrive at quantitatively and qualitatively optimal parameters.

In some embodiments, the Supply Chain Attributes Definition Module 440 can operate in several modes. In the first mode (“fixed network mode”), the physical attributes of the supply chain network upstream of leaf nodes are assumed to be fixed. This means that the locations and roles of different nodes in the supply chain are not considered to be free parameters of the optimization process. The actual outputs and behavior of each node may be highly variable, but the presence, role and operational characteristics of each node may not be changed by a user in this mode. To be specific, in this mode, the optimization process carried out by Orchestrated Intelligent Optimization Module 230 optimizes leaf node supply chain operational parameters such as reorder strategy, reorder frequency, safety stock level and others, subject to system-level constraints such as total orders serviced by each supply site per year. This is an optimization of certain parameters, holding the overall structure of the network fixed (although again, the actual outputs of this fixed system can be highly variable and may be modeled algorithmically by the system).

In another mode, the “fixed network end-to-end optimization mode”, the locations and roles of supply chain network nodes upstream from leaf nodes are considered to be fixed, but some of their operational parameters may be optimized subject to system-level constraints. In this mode, the amount of inventory to be held, the reorder frequency and strategy of the node and the allocation rules for supplying downstream nodes are examples of parameters that might be optimized by the Orchestrated Intelligent Supply Chain Ecosystem 100.

In yet another mode, the actual locations and roles of nodes across the entire supply chain may be optimized by the Orchestrated Intelligent Supply Chain Optimizer 150 (“full end-to-end network optimization mode”). In this mode, the actual opening, closing and modification of physical facilities may be contemplated as part of the optimization. For example, it may be more efficient to open a new upstream supply warehouse to service multiple complex products than to place increased demands on an existing warehouse that has reached operational capacity.

In some embodiments, users may suggest or test certain optimizations, in other options for optimization may be suggested entirely by algorithmic means (for example using machine learning or AI), and in others a combination of both user input and algorithmic suggestions may be employed, resulting in a system that can flexibly identify optimal supply chain configurations for different customer situations.

The consequential output of Supply Chain Attributes Definition Module 440 is a sufficient characterization of the quantitative aspects of the supply chain to allow the Orchestrated Intelligent Supply Chain Optimizer 150 to carry out the computations defined in Future Performance Predictor 450.

Future Performance Predictor 450 is a cornerstone of the Orchestrated Intelligent Optimization Module 230 in which future performance of the supply chain for each fixed set of operational parameters is predicted for the supply chain defined in Supply Chain Attributes Definition Module 440. In this module, each fixed set of operational parameters can be viewed as in input feature vector to the prediction module, and the predicted performances for all input feature vectors are then both archived and passed to Optimized Parameters and Sensitivities Computation Module 460 in order to perform constrained optimization on the entire system and to arrive at recommended operational parameters.

A variety of methods can be used to determine the complete set of input feature vectors to be used in Future Performance Predictor 450. For example, a fixed grid of parameter values (for example, reorder frequency, safety stock and upstream delivery performance variability) might be created and future predictions for all of these input feature vectors computed.

In some embodiments, an adaptive approach to input feature vector selection might be used to improve computational performance. For example, input feature vectors could be selected to follow along contours of fixed Service Level, or a gradient-based search algorithm could be employed to rapidly identify input feature vectors near local optima. Many different algorithmic approaches might be employed in this phase to build up a representation of the system behavior.

Given an input feature vector for the supply chain, the predicted future behavior may be determined by a variety of algorithmic methods. For example, one might train an AI system to predict future performance based on the input feature vector and supply chain network attributes. Alternatively, one might use a statistical approach to compute probabilities of different outcomes, such as a stockout or a reorder. Additionally, one might use a simulation approach to generate an ensemble of different future behaviors and then compute estimates and confidence levels of future outcomes based upon these ensembles. It is envisioned that a variety of algorithmic techniques may applied in this phase to predict the implications of different parameter selections. For example, a formal sensitivity analysis can be performed so that an estimate of the future outcome can be broken down into its constituent uncertainties and ranked so that the customer can be warned of the items that are the most pressing.

A critical component of the Future Performance Predictor 450 process is to forecast future product demand. In some embodiments, modeling and forecasting of product demand is performed entirely within this module and using algorithmic methods developed and/or implemented within the Orchestrated Intelligent Supply Chain Optimizer 150. In other embodiments, forecast sales values and or algorithmic formulations of product sales forecasts may be incorporated and used alongside internal forecast methodologies. Such an approach allows external business knowledge of future sales events (for example, promotional events, government drug purchase tenders, new product introductions, or expiration of a drug patent) to be incorporated into the prediction process, but not at the expense of advanced analytical prediction methods that have been developed internal to Orchestrated Intelligent Supply Chain Ecosystem 100.

The function of Optimized Parameters and Sensitivities Computation Module 460 is to identify optimal supply chain parameters based on the system performance predictions computed in Future Performance Predictor 450. The AI modelling algorithm seeks to identify based on the input parameters both imported and computational the optimal configuration response to meet targeted parameter constraints with the current and predicted levels of variability as identified in the input data. The models seek the optimal balance between service and target for that part of the supply chain selected for the computation. An additional function of Optimized Parameters and Sensitivities Computation Module 460 is to compute the relative sensitivities of recommended parameters to underlying variables. Each of these will be described below.

To identify optimal supply chain parameters, this module searches the space of all possible input feature vectors (the operational parameters of the supply chain that are desired to be optimized, such as reorder frequency and safety stock level for each product) and identifies an optimal set of such parameters, subject to the system-level constraints defined in Strategic Parameters and Constraints Definition Module 430.

In some embodiments, this process may be carried out in an iterative fashion in conjunction with Future Performance Predictor 450. There is a tradeoff between the granularity and completeness of the coverage of input feature vectors in Future Performance Predictor 450, which can generate a large amount of data and consume significant compute time, and the speed of the optimization and analysis process. The Orchestrated Intelligent Optimization Module 230 is designed to exploit these tradeoffs to provide maximal flexibility, accuracy and performance (including user experience) during the identification of optimal supply chain operational parameters.

In some embodiments, Future Performance Predictor 450 will include cost and impact computations that incorporate Global Factors such as environmental impact, cost of regulatory and voluntary offsets of such impacts, and other computed factors that might influence supply chain optimization. Some of these computations incorporate external costs of offset commodities and/or tax rates, which may be modeled within this module, or received as inputs to this module through inputs to the system from Global Factors Parameter Interface 255. In some embodiments, these inputs may be retrieved from live marketplaces in which offset and other Global Factor commodities are priced and traded in real time, and actual purchase/sale transactions of such commodities may be triggered (and/or executed) as part of the optimization computation (for example in order to ensure that the actual cost of the supply chain is consistent with the optimization computation).

The process to compute sensitivities of recommended supply chain operational parameters to underlying factors is carried out by comparing the predicted performance of the supply chain for input feature vectors near the recommended optimal parameters. By creating an internal model of the behavior of the system in the neighborhood of each recommended optimal parameters, the Optimized Parameters and Sensitivities Computation Module 460 can identify which factors are most likely to significantly alter the results of the analysis if they were to change, or if they were to be more accurately characterized in the data coming into the system at Data Management Module 220. Such results are presented to users at Data Management Module 220 and/or User Feedback Module 240, depending upon the permissions and characteristics of each user. In some embodiments, results from this analysis might be communicated to customer outside of the Orchestrated Intelligent Supply Chain Optimizer 150.

For example, the average inventory required to maintain a high Service Level for a product might be very sensitive to the Service Level, making it prudent to investigate whether such a high Service Level is indeed appropriate for the product. In another example, the sensitivity analysis may identify a modeled delivery performance that has a very large impact on underlying product availability performance. In such a case, the availability of this information to users allows the customer to make an informed decision about the value of investing resources to either more carefully characterize the delivery performance, or to actually take steps to improve the reliability of that delivery system. In either case, access to such sensitivity information is highly valuable to the customer in determining how to allocate assets and effort in the service of improving the overall performance of the stakeholder's respective supply chain.

A Results Prioritization Module (not illustrated) performs an analysis of all of the recommended parameter settings based on the optimization in Optimized Parameters and Sensitivities Computation Module 460 and then computes importance factors that determine how the results are displayed to the user. In some cases, all of the results might be presented in a single table, sorted in an order selected by the user. However, in many cases, because the number of products can be very large, it is critical to use analytical techniques to prioritize results and optimize the presentation of these results.

This is especially important given the fact that users have the option to use recommended optimal supply chain parameter values, or to override them. This means that after each analysis, there can be parameters that are far from their optimal values, and which subsequently can represent significant risk for the customer.

Hence, Results Prioritization Module applies analytical techniques (machine learning and AI in some embodiments) to determine which recommendations are most important to act on, for example because they mitigate risk or have large revenue implications. While this invention is applicable to supply chains in any industry or product area, as an example, consider an HIV product for which there are significant health implications if a stockout occurs. Because of changes in demand variability, or because of previously suboptimal manually set supply chain parameters, such a product might represent a significant risk to patients and the customer. Such a product would be assigned high priority in this module so that appropriate action could be taken by a user.

In some embodiments, Results Prioritization Module may trigger purchase and/or sale transactions of commodities (for example carbon offsets) that are required to perform the optimizations imagined in Future Performance Predictor 450. Once specific optimization choices are selected, the customer may elect to “lock in” the pricing of offsets or other commodities in order to ensure that the computations are reflective of actual conditions (in other words, to avoid changes in the price that might change the optimal solution or induce increased operational costs).

These prioritized results are transmitted to either Data Management Module 220 or User Feedback Module 240, depending upon what inputs they pertain to, and which kind of user is most appropriate to act upon them. For example, an adjustment to Service Level or safety stock level might be made by a Planner, but a project to investigate delivery performance at a supply chain node might be initiated by a supply chain manager or IT director.

Additionally, the Visualization Module 470 may take the output of the Results Prioritization Module and generate specific graphical representations of the output for user consumption.

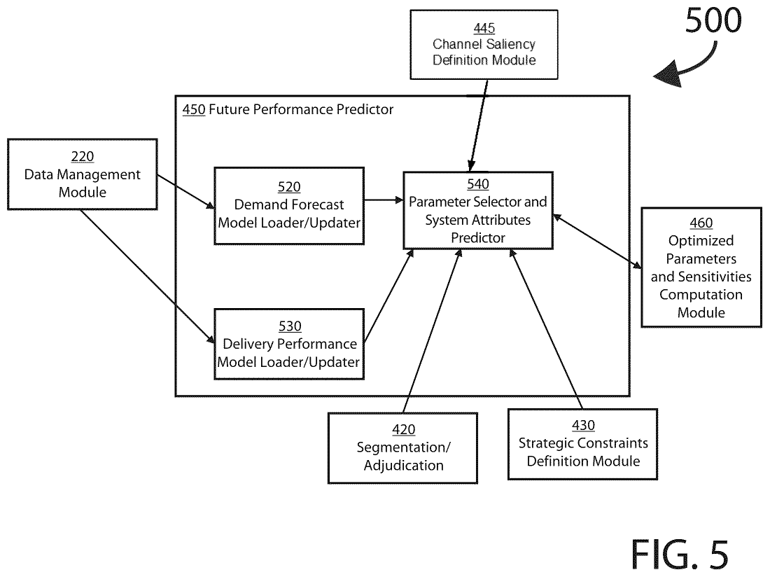

Referring now to FIG. 5, a critical component of the Future Performance Predictor 450 process is to forecast future product demand. In some embodiments, modeling and forecasting of product demand is performed entirely within this module and using algorithmic methods developed and/or implemented within the Orchestrated Intelligent Supply Chain Optimizer 150. In other embodiments, forecast sales values and or algorithmic formulations of product sales forecasts may be incorporated and used alongside internal forecast methodologies. Such an approach allows external business knowledge of future sales events (for example, promotional events, government drug purchase tenders, new product introductions, or expiration of a drug patent) to be incorporated into the prediction process, but not at the expense of advance analytical prediction methods that have been developed internal to the Orchestrated Intelligent Supply Chain Ecosystem 100.

In Demand Forecast Model Loader/Updater 520 internal modeling and forecasting assets are applied to product sales demand data from Data Management Module 220 to generate one or more product sales forecasts. In some embodiments, a customer generate forecast or forecasting model may be loaded in order to supplement the scope of future performance predictions.

In a parallel process of some embodiments, forecast and demand history time series data are updated in an ongoing monitoring process and a model representing the relationship between forecast and demand is updated. This model takes into account the likely variation between sales forecast and actual realized demand. For example, if the sales forecast is consistently higher than the actual demand, then the model will learn this. By a similar token, the model will learn the variability of actual demand relative to the single sales forecast.

This model of the relationship between sales forecast and demand history can be used to generate bias and noise terms for use in the regression calculation that generates the posterior distribution from the forecast and the prior.

Functions drawn from the posterior distribution can then be used as probability-weighted future demand scenarios in the construction of a SMSpace which can then be used in the global optimization of an end-to-end supply chain.

An important component of the Future Performance Predictor 450 process is to forecast future product delivery performance throughout the supply chain network. In some embodiments, modeling and forecasting of product delivery performance is performed entirely within this module and using algorithmic methods developed and/or implemented within the Orchestrated Intelligent Supply Chain Optimizer 150 as applied to historical delivery performance data. In other embodiments, historical delivery performance data may not be available, so supplementary information such as delivery performance models developed by the customer may be used.

In Delivery Performance Model Loader/Updater 530 internal modeling and forecasting assets are applied to historical delivery performance data from Data Management Module 220 to generate one or more estimates of future delivery performance. In some embodiments, a customer generated model or performance estimate may be loaded in order to supplement the scope of future performance predictions.

As described above, Future Performance Predictor 450 is a cornerstone of the Orchestrated Intelligent Optimization Module 230 in which future performance of the supply chain for each fixed set of operational parameters is predicted for the supply chain defined in Supply Chain Attributes Definition Module 440. In this module, each fixed set of operational parameters can be viewed as in input feature vector to the prediction module, and the predicted performances for all input feature vectors are then both archived and passed to Optimized Parameters and Sensitivities Computation Module 460 in order to perform constrained optimization on the entire system and to arrive at recommended operational parameters.

A variety of methods can be used in Parameter Selector and System Attributes Predictor 540 to determine the complete set of input feature vectors to be used in Future Performance Predictor 450. For example, a fixed grid of parameter values (for example, reorder frequency, safety stock and upstream delivery performance variability) might be created and future predictions for all of these input feature vectors computed.

In some embodiments, an adaptive approach to input feature vector selection might be used to improve computational performance. For example, input feature vectors could be selected to follow along contours of fixed Service Level, or a gradient-based search algorithm could be employed to rapidly identify input feature vectors near local optima. Many different algorithmic approaches might be employed in this phase to build up a representation of the system behavior.

Given an input feature vector for the supply chain attributes, parameters and/or configuration, the predicted future behavior may be determined by a variety of algorithmic methods. For example, one might train an AI system to predict future performance based on the input feature vector and supply chain network attributes. Alternatively, one might use a statistical approach to compute probabilities of different outcomes, such as a stockout or a reorder. Additionally, one might use a simulation approach to generate an ensemble of different future behaviors and then compute estimates and confidence levels of future outcomes based upon these ensembles. It is envisioned that a variety of algorithmic techniques may be applied in this phase to predict the implications of different parameter selections.

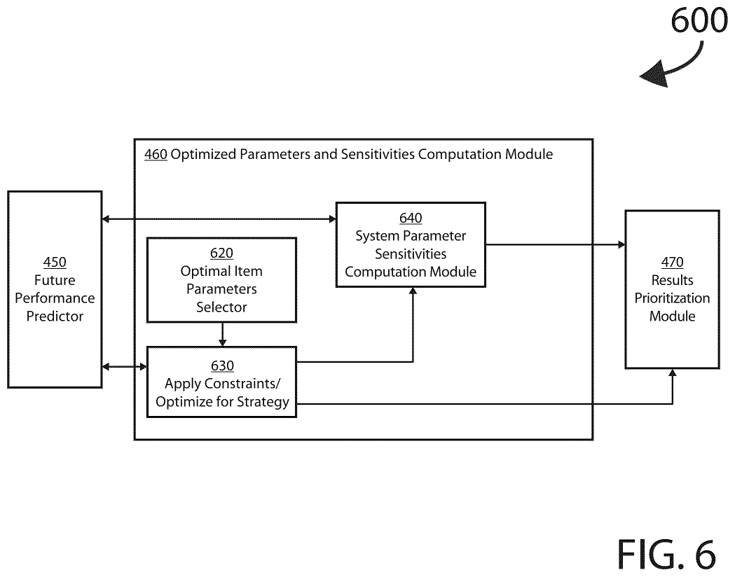

As shown in FIG. 6, the function of Optimized Parameters and Sensitivities Computation Module 460 is to identify optimal supply chain parameters based on the system performance predictions computed in Future Performance Predictor 450. An additional function of Optimized Parameters and Sensitivities Computation Module 460 is to compute the relative sensitivities of recommended parameters to underlying variables. Each of these will be described below.

To identify optimal supply chain parameters, the Optimal Item Parameters Selector 620 searches the space of all possible input feature vectors (the operational parameters of the supply chain that are desired to be optimized, such as reorder frequency and safety stock level for each product) and identifies an optimal set of such parameters, subject to the system-level constraints defined in Strategic Parameters and Constraints Definition Module 430. In some embodiments, Optimal Item Parameters Selector 620 works with Apply Constraints/Optimize for Strategy Module 630 in an iterative fashion to navigate the space of input feature vectors in order to determine the optimal set of parameters that satisfies system level constraints.

In some embodiments, this process may be carried out in an iterative fashion in conjunction with Future Performance Predictor 450. There is a tradeoff between the granularity and completeness of the coverage of input feature vectors in Future Performance Predictor 450, which can generate a large amount of data and consume significant compute time, and the speed of the optimization and analysis process. The Orchestrated Intelligent Optimization Module 230 is designed to exploit these tradeoffs to provide maximal flexibility, accuracy and performance (including user experience) during the identification of optimal supply chain operational parameters.

To identify optimal supply chain parameters, the Optimal Item Parameters Selector 620 module searches the space of all possible input feature vectors (the operational parameters of the supply chain that are desired to be optimized, such as reorder frequency and safety stock level for each product) and identifies an optimal set of such parameters, subject to the system-level constraints defined in Strategic Parameters and Constraints Definition Module 430. In some embodiments, Optimal Item Parameters Selector 620 works with Apply Constraints/Optimize for Strategy Module 630 in an iterative fashion to navigate the space of input feature vectors in order to determine the optimal set of parameters that satisfies system level constraints.

The process to compute sensitivities of recommended supply chain operational parameters to underlying factors is carried out in System Parameter Sensitivities Computation Module 640 by comparing the predicted performance of the supply chain for input feature vectors near the recommended optimal parameters. By creating an internal model of the behavior of the system in the neighborhood of each recommended optimal parameters, the Optimized Parameters and Sensitivities Computation Module 460 can identify which factors are most likely to significantly alter the results of the analysis if they were to change, or if they were to be more accurately characterized in the data coming into the system at Data Management Module 220. Such results are presented to users at Data Management Module 220 and/or User Feedback Module 240, depending upon the permissions and characteristics of each user. In some embodiments, results from this analysis might be communicated to customer outside of the Orchestrated Intelligent Supply Chain Optimizer 150.

For example, the average inventory required to maintain a high Service Level for a product might be very sensitive to the Service Level, making it prudent to investigate whether such a high Service Level is indeed appropriate for the product. In another example, the sensitivity analysis may identify a modeled delivery performance that has a very large impact on underlying product availability performance. In such a case, the availability of this information to users allows the customer to make an informed decision about the value of investing resources to either more carefully characterize the delivery performance, or to actually take steps to improve the reliability of that delivery system. In either case, access to such sensitivity information is highly valuable to the customer in determining how to allocate assets and effort in the service of improving the overall performance of the supply chain.

When limitations on supply chain resources are in effect (for example, when insufficient raw materials are available to make enough product to satisfy predicted demand) then optimization in Optimized Parameters and Sensitivities Computation Module 460 must incorporate Channel Saliency values to determine how to allocate products to specific channels. The results of this optimization can be parameterized as traditional supply chain planning parameters (for example safety stock and reorder amount) or they can be operated as a real time product routing system, in which the system directly computes and recommends movements of materials through the supply chain in order to satisfy constantly changing constraints in availability of resources, products and materials with simultaneously changing transportation performance and channel demand levels. Supply chain environments that experience frequent disruption often require such a constrained, real-time channel-sensitive optimization approach.

An example is in the case of pandemic disruption, where limited supply of vaccines needs to be administered, public health policy makers have to prioritize specific cohorts of patients based on ages and comorbidities and can define channels appropriately and can provide a relative prioritization. For example, a public health policy maker might define cohorts such as “Ages 50-60 and Gender is Male” or “Ages 70+ and has 2 or more comorbidities.” The system constructs channels based on the above definition and the public health policy maker can assign priorities to each of the above-mentioned channels. In addition to the channel data, demographic data within specified geographic regions is also taken into account in the simulation where it generates plans based on the distribution of the cohorts within geographic regions and the priorities defined by public health policy makers.

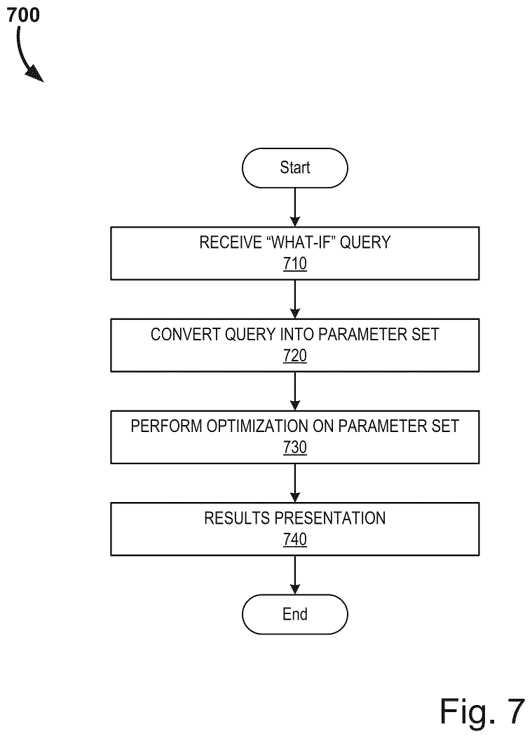

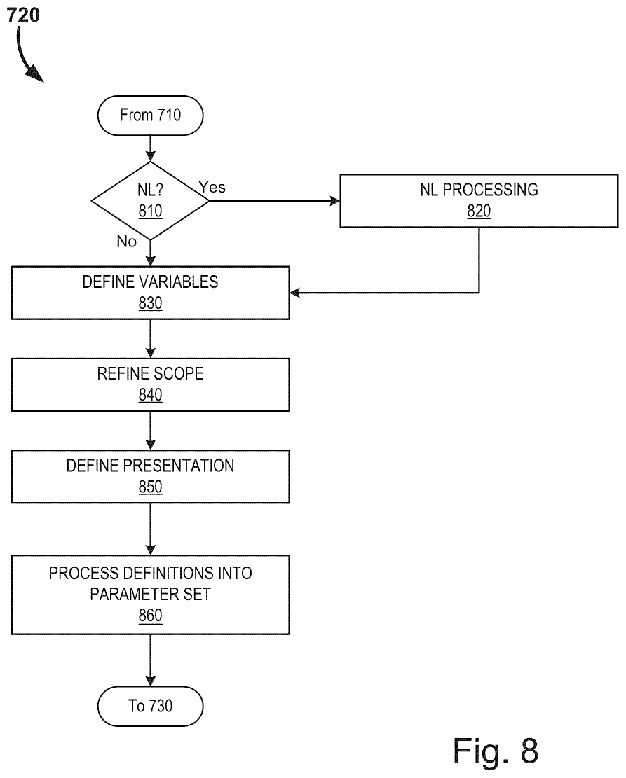

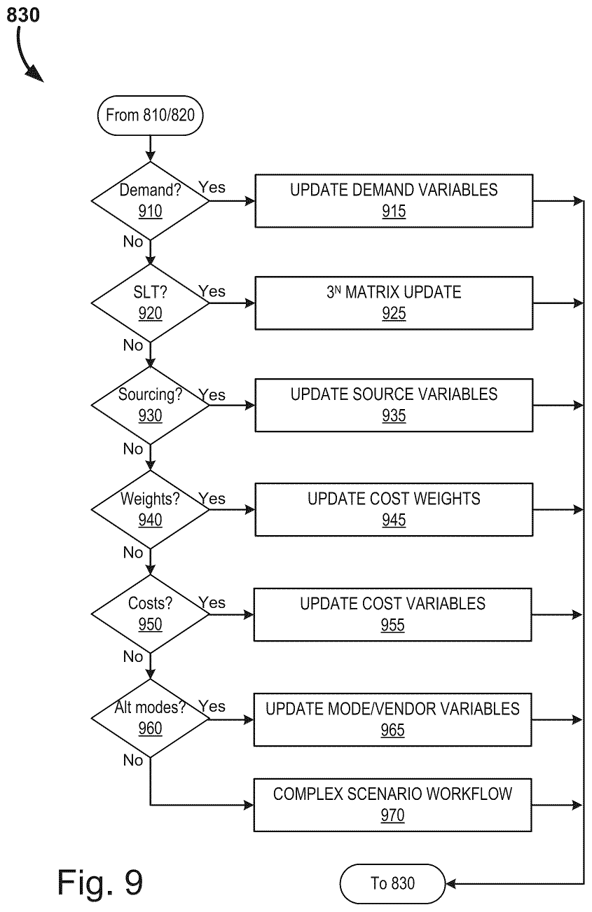

Turning now to FIG. 7, the process for performing hypothetical scenario optimizations is provided, shown generally at 700. Initially a “what-if” query is received from the user (at 710). The query is then converted into a set of parameters for the optimization process (at 720). FIG. 8 provides more details of this parameter generation process. Initially there is a determination if the query is a natural language (NL) query, or a selection of optimization scenario inputs (at 810). If the query is a NL query, the system performs NL processing (at 820) to convert the NL query into alterations of optimization inputs. Once these inputs have been identified, the variables of the optimization are defined (at 830). Variable definition is described in greater detail in relation to FIG. 9.

The process for variable definition includes performing a series of decisions regarding the type of variables that are impacted by the query. While these decisions are illustrated as being performed in series and in a specific order, it is contemplated in this disclosure that said decisions may be performed in parallel and/or in a different order. However, for the sake of clarity, the following decisions and possible resulting actions will be described in the order illustrated. Additionally, while it is illustrated that only one such set of variables may be updated, it is possible that a query may be compound and alter more than one variable set.

Initially there is a decision whether demand is at issue in the query (at 910). A demand query may include such questions as “what is the best supply chain if product X has a 20% sales volume lift due to a promotion?”. Alternatively, the user could select the product (or set of products) and input a demand change. When such a query is made, the demand variables for the model may be updated (at 915) to reflect this hypothetical scenario.

Another decision may be if the service level targets (SLTs) for a product or set of products are updated (at 920). If so, the user may be directed to a system for the generation of a 3^{N} matrix update (at 925). A 3^{N} matrix is a convenient tool for setting service level targets for sets of products based upon any designated set of variables. While the system is designed to support three variants of the given variable in the proposed 3^{N} matrix, this is not limiting. For example, the user may wish to perform a 4^{N} (or more) matrix for more granular decisions regarding a product.

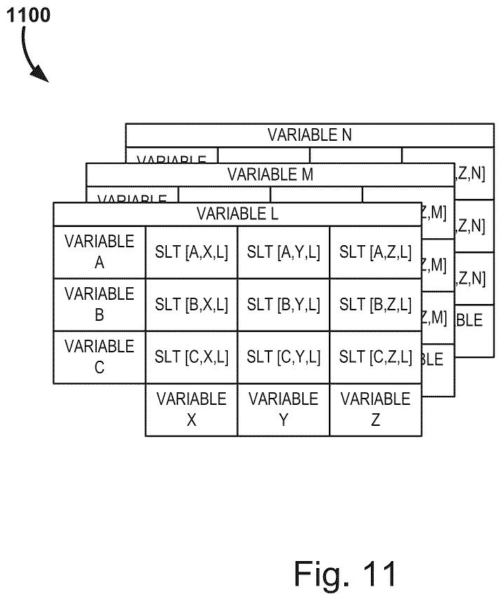

To assist in the understanding of setting a 3^{N} matrix, FIG. 11 provides an example 3³ matrix, shown generally at 1100. Such a matrix involves three variables, for a total of 27 inputs from the user. Generally, due to the large number of inputs needed, a 3³ matrix (three variables with three ‘buckets’) is the maximum number of variables/buckets a user wishes to configure. More frequently, a user is only interested in a 3² matrix for the sake of simplicity. In this example matrix, a set of products are divided into three “buckets” along each variable space. For example, variables A, B and C may be for the revenue each product generates. The ‘size’ of the buckets are also configurable. For example, variable A may be the top quartile of revenue, variable B is the middle 50% of products by revenue and variable C is the bottom quartile or products by revenue. In contrast, variables X, Y and Z, in this specific example, may be related to the coefficients of variation for the products. In this specific example variables L, M and N could be for levels of saliency, for example. It should be noted that any variables may be selected for each dimension of the matrix. For example, rather than revenue, sales volume or profit may be the distinguishing factor. Likewise, buckets may be varied in size.

For each cell in the matrix (here there are 27 cells), the user may input a minimum service level target. For example, a top revenue, high saliency, and large variation of coefficient cell may be afforded a 99% SLT. In comparison, a low saliency, low revenue and low coefficient of variation product may have a relatively low SLT of only 85%. Each combination of these variable spaces may receive a different SLT. By altering these values, the supply chain must dynamically alter based upon the optimization.

Returning to FIG. 9, another decision is whether the query includes a change in sourcing (at 930). If so, the sourcing variables may be updated (at 935). It should be noted that sourcing variable data is not always readily available, and the system may rely upon the imputation engine for missing variable elements. For example, sourcing information may include location information for the product origination, volumes available at each location for each time period, lead time history (lead times and/or lead time variability), product quality history, product pricing, carbon and other sustainability impacts. Some of this information is readily ascertained (e.g., source locations are a known elements), however other variables such as volumes available may not be known. For these variables, the imputation engine may use historical data to predict the missing variables. For example, the imputation engine may use data known for the volumes of similar products made at the new source, or volumes of the product made at a similarly sized source, to predict volumes that are available from the new source. As will be discussed further below, the imputation engine may calculate the confidence in the prediction. This data, in conjunction with the impact the variable has upon the optimization, may be used to determine the overall confidence in the hypothetical optimization results, and if there is actual measured data required to make an accurate optimization.

Another determination made by the system is if any cost weights need to be updated (at 940). The optimization is made using the following equation:

P=SLTₘᵢₙ≥ΣwᵢCᵢ Equation 1

Where P is the set of parameters for a given product, SLTₘᵢₙ is the minimum service level target for the given product, and Cᵢ is the series of costs for the supply chain and wᵢ are the weights associated with each cost. The weighted cost vector is provided in greater detail in relation to the following equation 2:

wᵢCᵢ=[w_{d}C_{d},w_{ch}C_{ch},wₛₕCₛₕ,w_{w}C_{w},w_{ci}C_{ci},w_{f}C_{f},wₛₒCₛₒ,w_{cbn}C_{cbn}] Equation 2

Where C_{d} is the cost of discards, C_{ch} is the cost of changeovers, Cₛₕ is the cost of shipping, C_{w} is the cost of warehousing, C_{ci} is the cost of inventory, C_{f} is the cost of “freshness”, Cₛₒ is the cost of stockouts and C_{cbn} is the cost of cardon emissions. ‘Freshness’ is defined as the length of a product until expiration once it has arrived at the final destination. Each cost is associated with a given weight. In a default optimization, each of these weights are set to one. This means the actual dollar cost is what is optimized for. However, in a what if query, there may be a desire to alter said weights in response to an actual or perceived disruption in the market, or for any other reason (e.g., publicity, consumer perception, etc.).

For example, an environmentally conscientious company may wish to prioritize carbon emissions above other cost factors. In such situations the weight for this cost may be adjusted upward by a commensurate amount.

Returning to FIG. 9, another decision that is made is if the underlying costs themselves are changing (at 950). This may be due to factors such as inflation, different vendors, and anticipated price changes. For example, there may be a union negotiation for shipping laborers that is going poorly, and the likelihood of a strike is high. It may then be advantageous to increase the cost of shipping to see how this may impact the supply chain. When such a change in cost is identified in the query the cost variables may be updated (at 955).

Another decision regarding variable changes is if there are alternative modes and vendors (at 960). For example, the user may wish to determine the impact of going from truck to rail for some segment of the supply chain. Such a shift has both cost and performance impacts, and these factors may be updated accordingly (at 965). Again, the imputation engine may be needed to inform missing variables on occasion based upon available historical data.

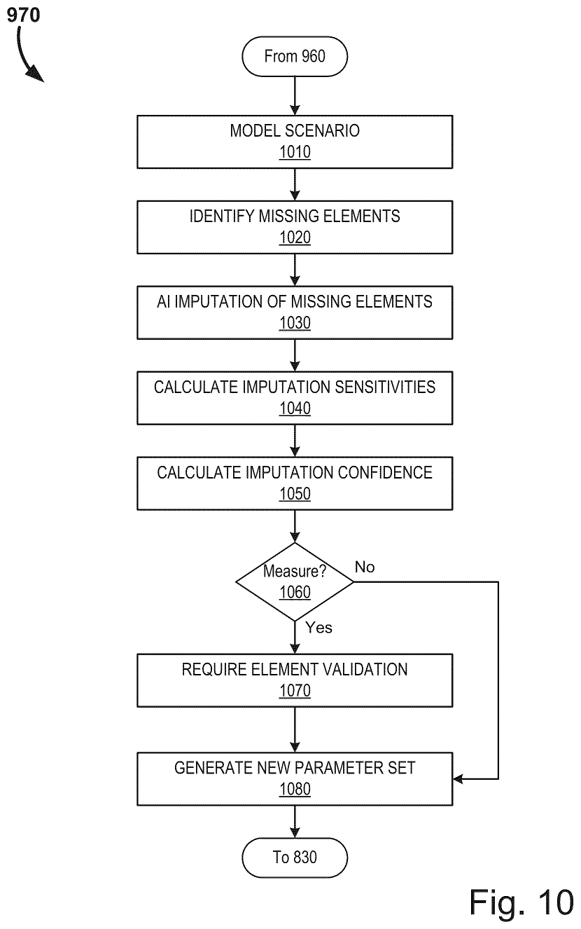

Lastly, the query may be a multi-variate complex scenario shift. For example, due to geo-political turmoil, it may be advantageous to model a situation where it is no longer possible to ship through a particular geography. This has significant impacts upon a number of costs and other parameters. When such a complex scenario is contemplated in the query, the system may undertake a separate workflow (at 970) to configure the optimization variables. FIG. 10 provides a more detailed example of the complex scenario workflow. The scenario itself needs to be initially modeled (at 1010). For example, if a geography cannot be utilized, new shipping routes and warehousing locations must be identified. Costs and time/performance for these new shipping routes and warehousing locations are needed. In some cases, this information is already known from past data sources. In other cases, the system may identify missing data elements (at 1020). The imputation engine may utilize AI algorithms to impute these missing values (at 1030). Again, imputation utilized other data points which are related to the missing data points to generate a prediction for the missing data points. For example, the cost of a warehouse may be imputed based upon the cost of other warehouse facilities in geographically similar locations (e.g., same region, same population densities, same number of surrounding warehousing facilities, etc.).

The sensitivities of the optimization for the given missing element(s) is determined (at 1040) based upon the optimization model. Elements that impact the model output significantly have a higher sensitivity, whereas model elements that have relatively small impact upon the performance may have a lower sensitivity. Likewise, the imputation engine is capable of determining the confidence in the prediction (at 1050). Confidence is based upon the AI algorithm's ability to accurately generate the prediction, and is directly related to the quality, quantity and relevancy of the data used to perform the prediction. For example, determining warehouse costs for a given warehouse, where the costs are known for a half dozen warehouses within a hundred-mile radius, and where the costs are consistent between the various warehouses, will generate an imputation for the warehouse cost with a very high degree of confidence. In contrast, if the warehouse is remote, and the closest three warehouses that have somewhat similar characteristics vary significantly in price, the system will generate a prediction with an extremely low confidence level. In some embodiments, the imputation model generates a prediction and a confidence interval.

Even when the confidence is low for a missing data element it does not necessarily mean that the modeled scenario is inaccurate or useless. What matters is the interplay of the imputation value's confidence and the sensitivity of the scenario model to the imputed value. When the model is very sensitive to the missing value, the need for the imputed value to be very accurate/high confidence is significantly higher. In contrast, low sensitivity to the missing value may tolerate a lower confidence level. In some embodiments, a ratio of the confidence level and the sensitivity may be generated. Only values over a configured threshold may be deemed “acceptable” for modeling. This ratio comparison may determine if there is a need to measure a given missing element, or if the scenario model is deemed acceptable (at 1060). When all missing elements are acceptable, a new set of parameters based upon the scenario model may be generated (at 1080). However, if some of the missing values are below a threshold/not acceptable, the system may send the user a validation requirement (at 1070). This validation may require the user to collect the missing information (e.g., contacting the warehouse for pricing data), or manually inputting the missing elements. Once validation of the missing data is performed, the system may complete the generation of the variable set.

Returning now to FIG. 8, after variables have all been defined, the system may refine the scope of the optimization (at 840). Scope refinement includes input from the user regarding the scenario optimization scope. For example, the user may wish to only perform the hypothetical optimization on a specific item, family of products or product area (e.g., cancer drugs, computer equipment, etc.). The scope may also be refined by region or specific market. It may also be filtered by network group, trade route, or by portfolio. Portfolios may be delineated by a given planner, company subsidiary, or other segmentation.

After refining the scope, the presentation may also be defined (at 850). As previously noted, the presentation may be set by the user, or may be auto configured based upon the query and/or optimization results. Presentation parameters may include plotting cost as a function of the variables being altered by the query, plotting service levels achieved as a function of the variables being altered by the query and recommendations of “best value” for the supply chain subject to the query variable changes. “Best value” may be based upon a cost optimization, a service level optimization or a composite of the two. The presentation may also include comparisons of the queried optimization versus the current supply chain. These side-by-side comparisons may include key elements as well as elements that diverge significantly between the two. This avoids information overload by displaying too many datapoints that are immaterial and/or similar between the hypothetical optimization and the currently optimized supply chain. Side-by-side comparison may be a global aggregation of results or more granular (e.g., individual item, SKU, network group, etc.). Lastly, the system may include automation that pre-computes results and generates alerts when certain conditions are met. For example, when an optimization is run the system may pre-analyze transport cost changes, for example, and generates alerts for high sensitivity areas (variables that will have a significant impact upon optimization results). This may avoid unnecessary hypothetical optimizations which are ‘known’ to provide significant detrimental impact to areas of high risk (e.g., lead times, lead time variability, etc.). This is advantageous given the computational demands of an optimization process are very high, and avoiding unnecessary optimizations saves both time of the user, and significant computational resources.

After all the definitions have been generated (variables, scope and presentation), the system may process these definitions to generate a parameter set for the optimization (at 860). Returning to FIG. 7, after the query has thus been converted to the parameter set, the hypothetical optimization may be performed using these parameters (at 730) as discussed in relation to FIGS. 4-6. The results of said optimization are then presented to the user (at 740) subject to the presentation definitions.

In some embodiments, after a scenario is presented to the user, there may be a feedback loop whereby the user accepts or declines recommendations generated by the system. In some cases, the system may present a series of various recommended scenarios, and the user may select from these recommendations. These feedback loops may be leveraged to train the machine learning algorithm for future scenario generation.

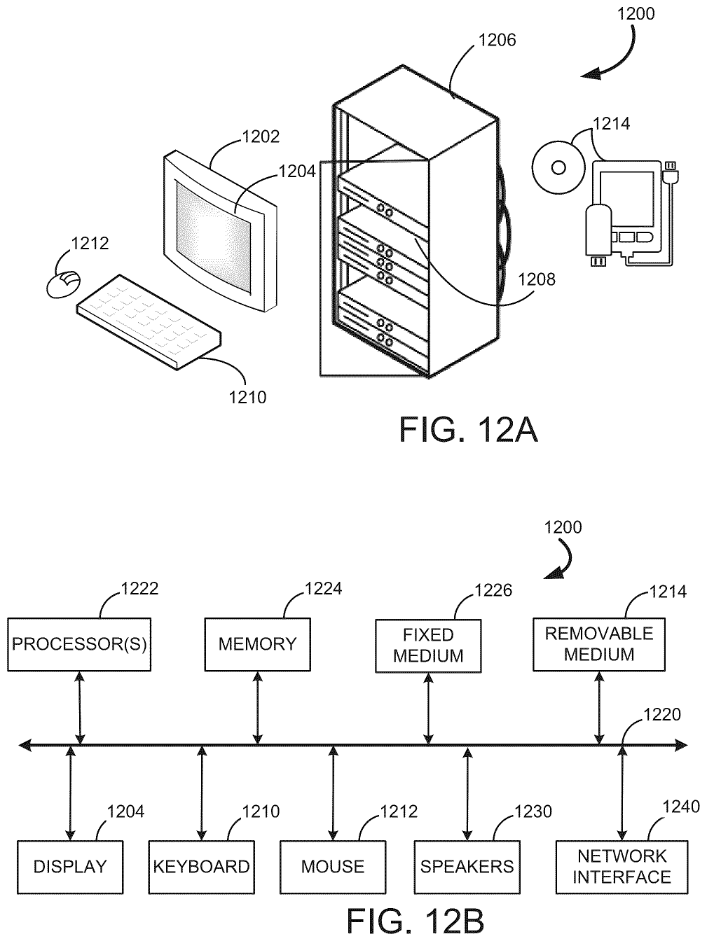

FIGS. 12A and 12B illustrate a Computer System 1200, which is suitable for implementing some embodiments of the present invention. FIG. 12A shows one possible physical form of the Computer System 1200. Of course, the Computer System 1200 may have many physical forms ranging from a printed circuit board, an integrated circuit, and a small handheld device up to a huge supercomputer. Computer system 1200 may include a Monitor 1202, a Display 1204, a Housing 1206, a Disk Drive and or Server Blade 1208, a Keyboard 1210, and a Mouse 1212. External storage 1214 is a computer-readable medium used to transfer data to and from Computer System 1200.

FIG. 12B is an example of a block diagram for Computer System 1200. Attached to System Bus 1220 are a wide variety of subsystems. Processor(s) 1222 (also referred to as central processing units, or CPUs) are coupled to storage devices, including Memory 1224. Memory 1224 includes random access memory (RAM) and read-only memory (ROM). As is well known in the art, ROM acts to transfer data and instructions uni-directionally to the CPU and RAM is used typically to transfer data and instructions in a bi-directional manner. Both of these types of memories may include any suitable of the computer-readable media described below. A Fixed Disk 1226 may also be coupled bi-directionally to the Processor 1222; it provides additional data storage capacity and may also include any of the computer-readable media described below. Fixed Disk 1226 may be used to store programs, data, and the like and is typically a secondary storage medium (such as a hard disk) that is slower than primary storage. It will be appreciated that the information retained within Fixed Disk 1226 may, in appropriate cases, be incorporated in standard fashion as virtual memory in Memory 1224. Removable Storage Medium 1214 may take the form of any of the computer-readable media described below.

Processor 1222 is also coupled to a variety of input/output devices, such as Display 1204, Keyboard 1210, Mouse 1212 and Speakers 1230. In general, an input/output device may be any of: video displays, track balls, mice, keyboards, microphones, touch-sensitive displays, transducer card readers, magnetic or paper tape readers, tablets, styluses, voice or handwriting recognizers, biometrics readers, motion sensors, brain wave readers, or other computers. Processor 1222 optionally may be coupled to another computer or telecommunications network using Network Interface 1240. With such a Network Interface 1240, it is contemplated that the Processor 1222 might receive information from the network or might output information to the network in the course of performing the above-described hypothetical supply chain optimization. Furthermore, method embodiments of the present invention may execute solely upon Processor 1222 or may execute over a network such as the Internet in conjunction with a remote CPU that shares a portion of the processing.

In addition, embodiments of the present invention further relate to computer storage products with a computer-readable medium that have computer code thereon for performing various computer-implemented operations. The media and computer code may be those specially designed and constructed for the purposes of the present invention, or they may be of the kind well known and available to those having skill in the computer software arts. Examples of computer-readable media include, but are not limited to: magnetic media such as hard disks, floppy disks, and magnetic tape; optical media such as CD-ROMs, DVDs or Blu-ray disks and holographic devices; magneto-optical media such as floppy or optical disks; and hardware devices that are specially configured to store and execute program code, such as application-specific integrated circuits (ASICs), programmable logic devices (PLDs) and ROM and RAM devices such as USB memory sticks. Examples of computer code include machine code, such as produced by a compiler, and files containing higher level code that are executed by a computer using an interpreter.

While this invention has been described in terms of several embodiments, there are alterations, modifications, permutations, and substitute equivalents, which fall within the scope of this invention. Although sub-section titles have been provided to aid in the description of the invention, these titles are merely illustrative and are not intended to limit the scope of the present invention. In addition, where claim limitations have been identified, for example, by a numeral or letter, they are not intended to imply any specific sequence.

It should also be noted that there are many alternative ways of implementing the methods and apparatuses of the present invention. It is therefore intended that the following appended claims be interpreted as including all such alterations, modifications, permutations, and substitute equivalents as fall within the true spirit and scope of the present invention.

What is claimed is:

1. A computerized method for hypothetical optimization of a supply chain, the method comprising:
receiving a hypothetical optimization query;
generating variable definitions responsive to the query;
generating scope definitions responsive to the query;
generating presentation definitions;
generating an optimization parameter set using the variable definitions and the scope definitions; and
optimizing a hypothetical supply chain responsive to the optimization parameter set via an artificial intelligence (AI) modeling platform.

2. The method of claim 1, wherein the variable definitions include at least one of demand variables, service level target (SLT) variables, source variables, cost weight variables, cost variables, mode and vendor variables, and complex scenario variables.

3. The method of claim 2, wherein the SLT variables are computed using an M^{N} matrix.

4. The method of claim 3, wherein the M^{N} matrix is a 3^{N} matrix.

5. The method of claim 2, wherein the parameter set is defined as:
P=SLTₘᵢₙ≥ΣwᵢCᵢ
Where P is the set of parameters for a given product, SLTₘᵢₙ is the minimum service level target for the given product, and Cᵢ is the series of costs for the supply chain and wᵢ are the weights associated with each cost.

6. The method of claim 5, wherein the weighted cost vector is defined as:
wᵢCᵢ=[w_{d}C_{d},w_{ch}C_{ch},wₛₕCₛₕ,w_{w}C_{w},w_{ci}C_{ci},w_{f}C_{f},wₛₒCₛₒ,w_{cbn}C_{cbn}]
Where C_{d} is the cost of discards, C_{ch} is the cost of changeovers, Cₛₕ is the cost of shipping, C_{w} is the cost of warehousing, C_{ci} is the cost of inventory, C_{f} is the cost of freshness, Cₛₒ is the cost of stockouts and C_{cbn} is the cost of cardon emissions.

7. The method of claim 6, wherein in a default optimization, each of the weights are set to one.

8. The method of claim 1, wherein the scope definitions include at least one of a specific item, a specific product family, a specific product area, a region, a market, a network group, a trade route and a portfolio.

9. The method of claim 1, wherein presentation definitions include at least one of plotting cost as a function of a query variable, plotting service level as a function of the query variable, recommendation of a best value subject to the query variable, comparison of the optimized hypothetical supply chain versus a current supply chain, and precomputed alerts.

10. The method of claim 1, further comprising generating at least one recommendation based upon the optimized hypothetical supply chain.

11. A computerized system for hypothetical optimization of a supply chain comprising:
an interface configured to receive a hypothetical optimization query; and
a server configured to generate variable definitions responsive to the query, generate scope definitions responsive to the query, generate presentation definitions, generate an optimization parameter set using the variable definitions and the scope definitions, and optimize a hypothetical supply chain responsive to the optimization parameter set via an artificial intelligence (AI) modeling platform.

12. The system of claim 11, wherein the variable definitions include at least one of demand variables, service level target (SLT) variables, source variables, cost weight variables, cost variables, mode and vendor variables, and complex scenario variables.

13. The system of claim 12, wherein the SLT variables are computed using an M^{N} matrix.

14. The system of claim 13, wherein the M^{N} matrix is a 3^{N} matrix.

15. The system of claim 12, wherein the parameter set is defined as:
P=SLTₘᵢₙ≥ΣwᵢCᵢ
Where P is the set of parameters for a given product, SLTₘᵢₙ is the minimum service level target for the given product, and Cᵢ is the series of costs for the supply chain and wᵢ are the weights associated with each cost.

16. The system of claim 15, wherein the weighted cost vector is defined as:
wᵢCᵢ=[w_{d}C_{d},w_{ch}C_{ch},wₛₕCₛₕ,w_{w}C_{w},w_{ci}C_{ci},w_{f}C_{f},wₛₒCₛₒ,w_{cbn}C_{cbn}]
Where C_{d} is the cost of discards, C_{ch} is the cost of changeovers, Cₛₕ is the cost of shipping, C_{w} is the cost of warehousing, C_{ci} is the cost of inventory, C_{f} is the cost of freshness, Cₛₒ is the cost of stockouts and C_{cbn} is the cost of cardon emissions.

17. The system of claim 16, wherein in a default optimization, each of the weights are set to one.

18. The system of claim 11, wherein the scope definitions include at least one of a specific item, a specific product family, a specific product area, a region, a market, a network group, a trade route and a portfolio.

19. The system of claim 11, wherein presentation definitions include at least one of plotting cost as a function of a query variable, plotting service level as a function of the query variable, recommendation of a best value subject to the query variable, comparison of the optimized hypothetical supply chain versus a current supply chain, and precomputed alerts.

20. The system of claim 11, wherein the server is further configured to generate at least one recommendation based upon the optimized hypothetical supply chain.
